(19) United States
(12) Patent Application Publication
(10) Pub. No.: US 2025/0353453 A1
(43) Pub. Date: Nov. 20, 2025

(54) WIRING BOARD

(71) Applicant: YAZAKI CORPORATION, Tokyo (JP)

(72) Inventors: Hideaki Kikuchi, Susono-shi (JP); Hiroyuki Ogura, Susono-shi (JP)

(21) Appl. No.: 19/290,358

(22) Filed: Aug. 5, 2025

Related U.S. Application Data
(63) Continuation of application No. PCT/JP2024/003720, filed on Feb. 5, 2024.

(30) Foreign Application Priority Data
Mar. 6, 2023 (JP) 2023-033805

(51) Int. Cl. B60R 16/02; H05K 1/18; H05K 7/14

(52) U.S. Cl. CPC B60R 16/0215; H05K 1/181; H05K 7/1407; H05K 2201/09227; H05K 2201/10189; H05K 2201/10287

(57) ABSTRACT

A wiring board includes a panel attached to a vehicle body and partitioning the vehicle body into a vehicle interior and a front compartment, and a wiring disposed on the panel. The wiring is attached to a surface on the vehicle interior side or a surface on the front compartment side.

### CROSS-REFERENCE TO RELATED APPLICATIONS

This is a continuation of International Application No. PCT/JP2024/003720 filed on Feb. 5, 2024, and claims priority from Japanese Patent Application No. 2023-033805 filed on Mar. 6, 2023, the entire content of which is incorporated herein by reference.

### TECHNICAL FIELD

The present disclosure relates to a wiring board.

### BACKGROUND ART

Various electronic devices are mounted on an instrument panel in front of a driver's seat and a passenger seat in a vehicle interior. Therefore, it is necessary to provide a wire harness (wiring) to be connected to the electronic device around the instrument panel. Further, the instrument panel is provided with a reinforcing member called a “reinforcement” extending in a left-right direction. In the related art, a wire harness to be connected to an electronic device is supported by a reinforcement as disclosed in, for example, JP2019-119287A. Specifically, in the wire harness, a trunk line extending in the left-right direction is supported by the reinforcement, and branch lines branching off from the trunk line extend downward and are connected to the electronic device.

However, since the wire harness provided with the plurality of branch lines has a complicated shape, it is necessary to manually assemble the wire harness to a vehicle, and there is a problem that assembly work becomes complicated.

The present disclosure provides a wiring board that facilitates assembly work of wiring to the vicinity of an instrument panel.

### SUMMARY OF INVENTION

In order to achieve the above object, a wiring board according to the present disclosure has the following features.

A wiring board includes a panel attached to a vehicle body and partitioning the vehicle body into a vehicle interior and a front compartment, and a wiring disposed on the panel. The wiring is attached to a surface on the vehicle interior side or a surface on the front compartment side.

A wiring board includes a panel attached to a vehicle body and partitioning the vehicle body into a vehicle interior and a front compartment a wiring disposed on the panel, and a conductive fixing portion configured to attach the panel to the vehicle body. The wiring includes a body ground wire. The body ground wire is body-grounded to the vehicle body via the fixing portion. The wiring is formed as a printed wiring printed on the panel. The fixing portion is implemented by a bolt. The panel is provided with a first bolt-through hole through which the bolt is passed. An end of the body ground wire is printed on at least one edge portion of the first bolt-through hole. The bolt is passed through the first bolt-through hole of the panel to attach the panel to the vehicle body.

### Advantageous Effects of Invention

According to the present disclosure, it is possible to provide the wiring board that facilitates the assembly work of the wiring to the vicinity of the instrument panel.

The present disclosure has been briefly described above. Further, the details of the present disclosure can be clarified by reading modes (hereinafter, referred to as “embodiments”) for carrying out the disclosure described below with reference to the accompanying drawings.

### BRIEF DESCRIPTION OF DRAWINGS

FIG. 1 is a configuration diagram illustrating a wiring board according to a first embodiment;

FIG. 2 is a schematic cross-sectional view of a state in which the wiring board illustrated in FIG. 1 is attached to a vehicle body;

FIG. 3 is a configuration diagram illustrating a wiring board according to a second embodiment; and

FIG. 4 is a schematic cross-sectional view of a state in which the wiring board illustrated in FIG. 3 is attached to a vehicle body.

### DESCRIPTION OF EMBODIMENTS

Specific embodiments according to the present disclosure will be described below with reference to the drawings.

### First Embodiment

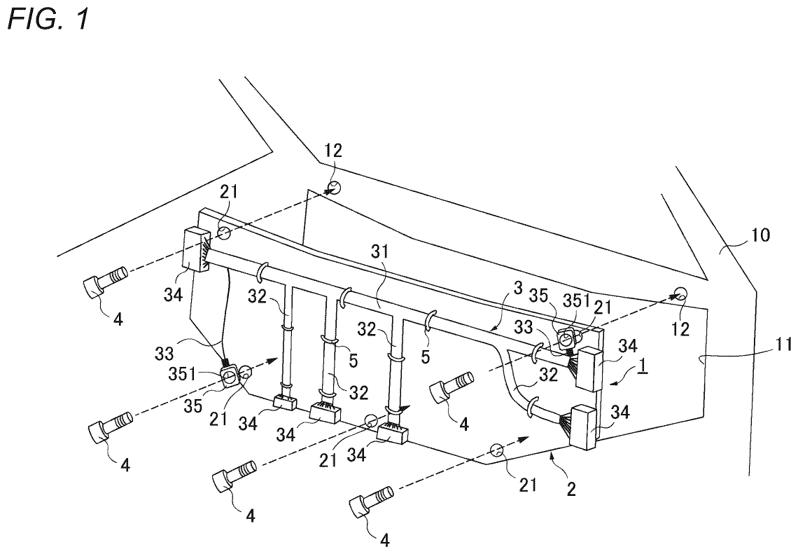

A wiring board of a first embodiment will be described with reference to FIG. 1. As shown in FIG. 1, a wiring board 1 is attached to a vehicle body 10 made of metal, and includes a panel 2 that partitions the vehicle body 10 into a vehicle interior and a front compartment provided in front of the vehicle interior, and a wire harness 3 serving as wiring disposed on the panel 2.

Next, the vehicle body 10 to which the above-described wiring board 1 is attached will be described. The vehicle body 10 to which the wiring board 1 of the present embodiment is attached is formed by casting using a large mold.

The vehicle body 10 formed by casting using the large mold has high strength. Therefore, a partition wall between the vehicle interior and the front compartment does not need to have enough strength to maintain a shape of the vehicle body. Accordingly, it is not necessary to integrally form the vehicle body 10 and the partition wall, and a separate partition wall can be adopted.

In addition, in the case of an electric automobile on which no engine is mounted, there is no internal combustion engine, a high temperature is hardly generated, and noise is small. For this reason, not only metal but also a resin can be adopted as the partition wall in the vehicle body 10.

For the reasons described above, in the present embodiment, the wiring board that is attached to the vehicle body 10 of the electric automobile on which no engine is mounted, is formed by casting, and adopts the resin panel 2 as the partition wall is exemplified.

A vehicle interior in which a driver's seat, a passenger seat, and a rear seat are disposed, and a front compartment provided in front of the vehicle interior are formed in the vehicle body 10. In the vehicle body 10, there is no partition wall between the vehicle interior and the front compartment, and an opening 11 is provided. The resin panel 2 is formed in a shape that closes the opening 11 between the vehicle interior and the front compartment.

The resin panel 2 is provided with bolt-through holes (=first bolt-through holes) 21 through which bolts 4 as metal (conductive) fixing portions for attaching the resin panel 2 to the vehicle body 10 are passed. The plurality of bolt-through holes 21 are provided along a peripheral edge of the resin panel 2.

The wire harness 3 is attached to a surface on a vehicle interior side of the resin panel 2. The wire harness 3 is provided by bundling a plurality of electric wires with a tape or the like. In the present embodiment, the wire harness 3 includes a trunk line 31 extending in a left-right direction, branch lines 32 branching off from the trunk line 31 and extending downward, and body ground wires 33 branching off from the trunk line 31. Connectors 34 for connecting to an electronic device or the like disposed on an instrument panel is attached to both ends of the trunk line 31 in the left-right direction and ends of the branch lines 32. A terminal 35 provided with a bolt-through hole (=second bolt-through hole) 351 through which the bolt 4 is passed is attached to an end of the body ground wire 33. In the example shown in FIG. 1, the body ground wire 33 branches off from the trunk line 31, but the present disclosure is not limited thereto, and the body ground wire 33 may branch off from the branch line 32.

The wire harness 3 is fixed to the resin panel 2 by harness clips 5. In the example illustrated in FIG. 1, the wire harness 3 is fixed to the resin panel 2 by the harness clips 5, but the present disclosure is not limited thereto, and the wire harness 3 may be fixed to the resin panel 2 by an adhesive or the like.

Next, a manufacturing process of the above-described wiring board 1 and attachment of the wiring board 1 to the vehicle body 10 will be described. In the present embodiment, the resin panel 2 is used as a routing board, the electric wires are routed on the resin panel 2, tape winding or the like is performed, the routed electric wires are bundled to form the wire harness 3, and then the wire harness 3 is fixed to the resin panel 2 using the harness clips 5.

Next, the resin panel 2 to which the wire harness 3 is fixed is attached to the vehicle body 10. A bolt-through hole 12 through which the bolt 4 is passed is provided at an edge portion of the opening 11 between the vehicle interior and the front compartment provided in the vehicle body 10. An edge portion of the resin panel 2 overlaps the edge portion of the opening 11 provided in the vehicle body 10, and the bolt-through hole 12 provided in the vehicle body 10 overlaps the bolt-through hole 21 provided in the resin panel 2. Further, the bolt-through hole 351 of the terminal 35 provided at the end of the body ground wire 33 overlaps the bolt-through hole 21 provided in a surface on the vehicle interior side of the resin panel 2.

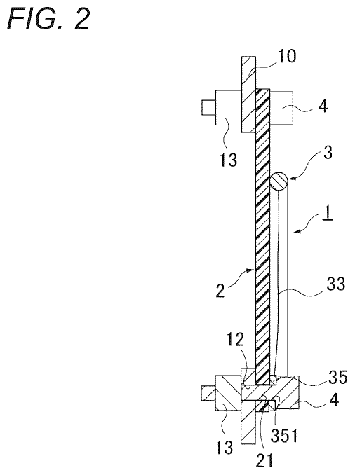

Then, as shown in FIG. 2, the bolt 4 is passed through the terminal 35, the resin panel 2, and the bolt-through holes 351, 21, and 12 provided in the vehicle body 10, and is fastened using a nut 13. Accordingly, the body ground wire 33 is electrically connected to the vehicle body 10 via the bolt 4. In the present embodiment, since two terminals 35 are provided, two of the five bolts 4 pass through the bolt-through holes 351 provided in the terminals 35. The remaining bolts 4 pass through the resin panel 2 and bolt-through holes 21 and 12 provided in the vehicle body 10 without passing through the terminals 35, and are fastened using the nuts 13.

According to the above-described embodiment, the wire harness 3 can be assembled to the vicinity of the instrument panel only by attaching the resin panel 2 on which the wire harness 3 is disposed so as to close the opening between the vehicle interior and the front compartment. Since the resin panel 2 can be gripped by a robot hand, the wiring board 1 can also be automatically assembled to the vehicle body 10. Accordingly, assembly work of the wire harness 3 to the vicinity of the instrument panel is facilitated.

According to the above-described embodiment, the vehicle body 10 is a vehicle body of the electric vehicle and is formed by casting. Accordingly, the resin panel 2 can be used as a partition between the vehicle interior and the front compartment.

According to the above-described embodiment, the body ground wire 33 is body-grounded to the vehicle body 10 via the bolt 4. Accordingly, since it is not necessary to perform connection work of the body ground wire 33 to the vehicle body 10 separately from attachment work of the resin panel 2, the assembly work is further facilitated. Further, it is not necessary to extend the body ground wire 33 to the outside of the resin panel 2 for connection to the vehicle body 10.

According to the above-described embodiment, the bolt 4 is passed through the bolt-through hole 21 of the resin panel 2 and the bolt-through hole 351 of the terminal 35 attached to the end of the body ground wire 33, and the resin panel 2 is attached to the vehicle body 10. Accordingly, when the resin panel 2 is attached by the bolts 4, the body ground wires 33 can be connected to the vehicle body 10 via the bolts 4 only by passing the bolts 4 through the terminals 35 connected to the ends of the body ground wires 33.

### Second Embodiment

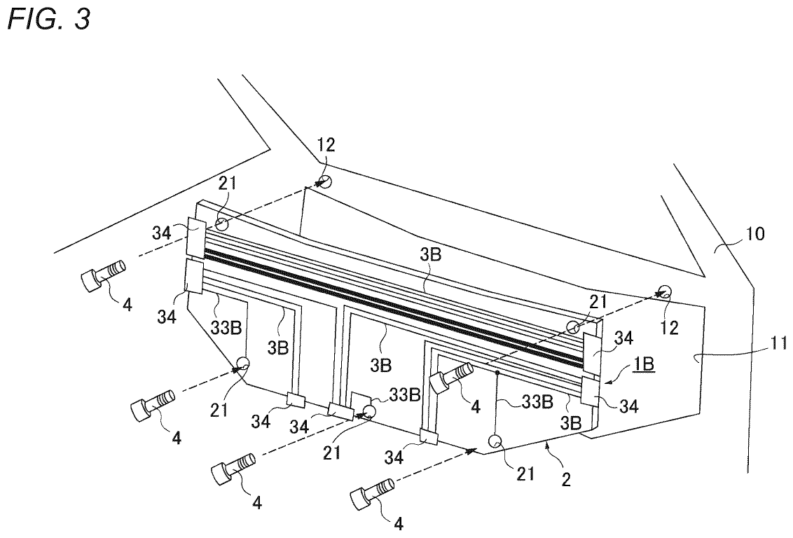

Next, a wiring board 1B of a second embodiment will be described with reference to FIG. 3. In FIG. 3, the same reference signs are given to the same parts as those of the wiring board 1 of FIG. 1 already described in the first embodiment described above, and the detailed description thereof will be omitted. As illustrated in FIG. 3, the wiring board 1 is attached to the vehicle body 10 made of metal, and includes the resin panel 2 made of a resin that partitions the vehicle body 10 into the vehicle interior and the front compartment, and pieces of printed wiring 3B as a plurality of pieces of wiring printed on the resin panel 2.

Similarly to the first embodiment, the vehicle body 10 to which the wiring board 1B of the second embodiment is attached is a vehicle body of an electric vehicle and is formed by casting using a large mold. Since the resin panel 2 of the second embodiment is similar to that of the first embodiment, a detailed description thereof will be omitted here.

The plurality of pieces of printed wiring 3B are formed by printing on the resin panel 2. In the present embodiment, some of the plurality of pieces of printed wiring 3B extend rightward from a left end of the resin panel 2 to a right end of the resin panel. Some of the plurality of pieces of printed wiring 3B extend rightward from the left end of the resin panel 2, then bend downward, and extend to a lower end of the resin panel 2. Further, some of the plurality of pieces of printed wiring 3B extend leftward from the right end of the resin panel 2, then bend downward, and extend to the lower end of the resin panel 2. Connectors 34 are connected to both ends of the plurality of pieces of printed wiring 3B. The connector 34 is implemented by, for example, an edge connector.

Some of the plurality of pieces of printed wiring 3B become body ground wires 33B, and an end of the printed body ground wire 33B is provided at an edge portion of the bolt-through hole 21 of the resin panel 2. In the present embodiment, since three body ground wires 33B are provided, the ends of the body ground wires 33B are provided at three edge portions of the five bolt-through holes 21. The ends of the body ground wires 33B are not provided at the edge portions of the remaining bolt-through holes 21.

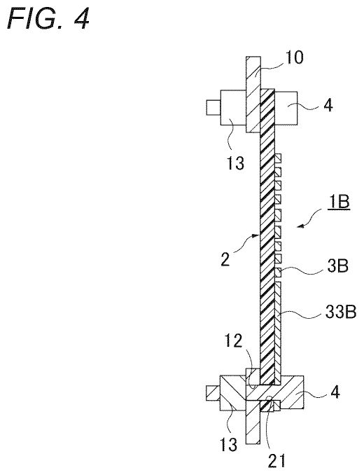

Next, the attachment of the above-described wiring board 1B to the vehicle body 10 will be described. The edge portion of the resin panel 2 overlaps the edge portion of the opening 11 provided in the vehicle body 10, and the bolt-through hole 12 provided in the vehicle body 10 overlaps the bolt-through hole 21 provided in the resin panel 2. Then, as illustrated in FIG. 4, the bolt 4 passes through the bolt-through hole 21 provided in the resin panel 2 and the vehicle body 10, and is fastened using the nut 13 (not shown). Accordingly, since the end of the body ground wire 33B is printed on the edge portion of the bolt-through hole 21 of the resin panel 2, the body ground wire 33B is electrically connected to the vehicle body 10 via the bolt 4.

According to the above-described embodiment, the printed wiring 3B can be assembled to the vicinity of the instrument panel only by attaching the resin panel 2 on which the printed wiring 3B is printed and disposed so as to close the opening between the vehicle interior and the front compartment. Since the resin panel 2 can be gripped by a robot hand, the wiring board 1 can also be automatically assembled to the vehicle body 10. Accordingly, the assembly work of the printed wiring 3B to the vicinity of the instrument panel is facilitated.

According to the above-described embodiment, the bolt 4 is passed through the bolt-through hole 21 of the resin panel 2, and the resin panel 2 is attached to the vehicle body 10. Accordingly, the body ground wire 33B can be connected to the vehicle body 10 via the bolt 4 only by attaching the resin panel 2 with the bolt 4.

The present disclosure is not limited to the embodiments described above, and modification, improvement, and the like thereof can be made as appropriate. Materials, shapes, sizes, numbers, arrangement positions, and the like of components in the embodiments described above are freely selected and are not limited as long as the present disclosure can be implemented.

For example, the material of the panel that partitions the vehicle interior and the front compartment and on which the wire harness 3 and the printed wiring 3B are disposed is not limited to a resin, and may be metal or carbon.

In the first embodiment described above, the resin panel 2 is used as the routing board for the wire harness 3, but the disclosure is not limited thereto. The wire harness 3 may be formed using a routing board different from the resin panel 2, and then the formed wire harness 3 may be mounted and fixed on the resin panel 2.

In the above-described second embodiment, the printed wiring 3B is printed only on the surface on the vehicle interior side of the resin panel 2, but the disclosure is not limited thereto. The printed wiring 3B may also be provided on a surface on a front compartment side of the resin panel 2. One surface of the resin panel 2 may be a ground surface or a ground wiring surface. The resin panel 2 may be provided in multiple layers, and the printed wiring 3B may be provided on both surfaces of each layer.

In the above-described second embodiment, an example in which the edge connector is used as the connector 34 has been described, but the present disclosure is not limited thereto. A surface mount type connector may be adopted as the connector 34. Further, a through connector that penetrates the resin panel 2 may be adopted as a connector 34, and an electronic device disposed in the vehicle interior and an electronic device disposed in the front compartment may be connected to the through connector.

### Third Embodiment

A wiring board of a third embodiment will be described with reference to FIG. 1 similarly to the first embodiment. The third embodiment is a wiring board employed in an automobile on which an engine is mounted. As shown in FIG. 1, the wiring board 1 is attached to the vehicle body 10 made of metal, and includes the panel 2 that partitions the vehicle body 10 into a vehicle interior and a front compartment provided in front of the vehicle interior, and the wire harness 3 serving as wiring disposed on the panel 2.

The vehicle body 10 to which the wiring board 1 of the third embodiment is attached is also formed by casting using a large mold. Since the strength of the vehicle body is high, it is not necessary to integrally form the vehicle body and the partition wall, and a separate partition wall is adopted.

The vehicle body 10 to which the wiring board 1 of the third embodiment is attached is an automobile on which an engine is mounted. In the case of the automobile on which the engine is mounted, there is an internal combustion engine, the temperature is likely to become high, and noise is loud. Therefore, from the viewpoint of safety and comfort, metal is adopted as the partition wall between the vehicle interior and the front compartment. Other configurations are similar to those of the first embodiment.

According to the first to third embodiments described above, the vehicle body 10 is formed by casting, but the vehicle body 10 is not limited to being formed by casting as long as the panel 2 can be adopted. For example, the vehicle body 10 may be formed by forging.

Here, features of the embodiments of the wiring board according to the present disclosure described above are briefly summarized and listed in the following first to fifth aspects.

### (First Aspect)

A wiring board (1, 1B) including:
a panel (2) attached to a vehicle body (10) and partitioning the vehicle body (10) into a vehicle interior and a front compartment; and
wiring (3, 3B) disposed on the panel (2).

According to the above configuration of the first aspect, the wiring (3, 3B) can be assembled to the vicinity of an instrument panel only by attaching the panel (2) on which the wiring (3, 3B) is disposed between the vehicle interior and the front compartment. Accordingly, assembly work of the wiring (3, 3B) to the instrument panel is facilitated.

### (Second Aspect)

The wiring board (1, 1B) according to the first aspect, in which
the wiring (3, 3B) includes a trunk line (31) extending in a left-right direction, and branch lines (32) branching off from the trunk line (31) and extending downward.

### (Third Aspect)

The wiring board (3, 3B) according to the first aspect, in which
the panel (2) is made of a resin.

According to the above configuration of the third aspect, since the panel (2) is made of an insulating resin, the wiring (3, 3B) is easily disposed.

### (Fourth Aspect)

The wiring board (1, 1B) according to the first aspect, further including:
a conductive fixing portion (4) configured to attach the panel (2) to the vehicle body (10), in which
the wiring (3, 3B) includes a body ground wire (33, 33B), and
the body ground wire (33, 33B) is body-grounded to the vehicle body (10) via the fixing portion (4).

According to the above configuration of the fourth aspect, since it is not necessary to perform connection work of the body ground wire (33, 33B) to the vehicle body (10) separately from attachment work of the panel (2), the assembly work is further facilitated. Further, it is not necessary to extend the body ground wire (33, 33B) to the outside of the panel (2) for connection to the vehicle body (10).

### (Fifth Aspect)

The wiring board (1) according to the third aspect, in which
the wiring (3, 3B) is implemented by a wire harness (3) in which a plurality of electric wires are bundled,
the fixing portion (4) is implemented by a bolt (4),
the panel (2) is provided with a first bolt-through hole (21) through which the bolt (4) is passed,
a terminal (35) provided with a second bolt-through hole (351) through which the bolt (4) is passed is attached to an end of the body ground wire (33), and
at least one of the bolts (4) is passed through the first bolt-through hole (21) of the panel (2) and the second bolt-through hole (351) of the terminal (35) to attach the panel (2) to the vehicle body (10).

With the above configuration of the fifth aspect, when the panel (2) is attached by the bolt (4), the body ground wire (33) can be connected to the vehicle body (10) via the bolt (4) only by passing the bolt (4) through the terminal (35) connected to the end of the body ground wire (33).

### (Sixth Aspect)

A wiring board (1B) including:
a panel (2) attached to a vehicle body (10) and partitioning the vehicle body (10) into a vehicle interior and a front compartment;
a wiring (3, 3B) disposed on the panel; and
a conductive fixing portion (4) configured to attach the panel (2) to the vehicle body (10), in which
the wiring (3, 3B) includes a body ground wire (33, 33B),
the body ground wire (33, 33B) is body-grounded to the vehicle body (10) via the fixing portion (4), and
the wiring (3, 3B) is implemented by a printed wiring (3B) printed on the panel (2),
the fixing portion (4) is implemented by a bolt (4),
the panel (2) is provided with a first bolt-through hole (21) through which the bolt (4) is passed,
an end of the body ground wire (33B) is printed on at least one edge portion of the first bolt-through hole (21), and
the bolt (4) is passed through the first bolt-through hole (21) of the panel (2) to attach the panel (2) to the vehicle body (10).

According to the above configuration of the sixth aspect, the body ground wire (33B) can be connected to the vehicle body (10) via the bolt (4) only by attaching the panel (2) with the bolt (4).

Although the present disclosure is described in detail and with reference to the specific embodiments, it is apparent to those skilled in the art that various changes and modifications can be made without departing from the spirit and scope of the present disclosure.

What is claimed is:

1. A wiring board comprising:
a panel attached to a vehicle body and partitioning the vehicle body into a vehicle interior and a front compartment; and
a wiring disposed on the panel, wherein
the wiring is attached to a surface on the vehicle interior side or a surface on the front compartment side.

2. The wiring board according to claim 1, wherein
the wiring includes a trunk line extending in a left-right direction, and branch lines branching off from the trunk line and extending downward.

3. The wiring board according to claim 1, wherein
the panel is made of a resin.

4. The wiring board according to claim 1, further comprising:
a conductive fixing portion configured to attach the panel to the vehicle body, wherein
the wiring includes a body ground wire, and
the body ground wire is body-grounded to the vehicle body via the fixing portion.

5. The wiring board according to claim 4, wherein
the wiring is formed as a wire harness in which a plurality of electric wires are bundled,
the fixing portion is formed as a plurality of bolts,
the panel is provided with a first bolt-through hole,
a terminal provided with a second bolt-through hole is attached to an end of the body ground wire, and
at least one of the bolts is passed through the first bolt-through hole of the panel and the second bolt-through hole of the terminal to attach the panel to the vehicle body.

6. A wiring board comprising:
a panel attached to a vehicle body and partitioning the vehicle body into a vehicle interior and a front compartment;
a wiring disposed on the panel; and
a conductive fixing portion configured to attach the panel to the vehicle body, wherein
the wiring includes a body ground wire,
the body ground wire is body-grounded to the vehicle body via the fixing portion,
the wiring is formed as a printed wiring printed on the panel,
the fixing portion is implemented by a bolt,
the panel is provided with a first bolt-through hole through which the bolt is passed,
an end of the body ground wire is printed on at least one edge portion of the first bolt-through hole, and
the bolt is passed through the first bolt-through hole of the panel to attach the panel to the vehicle body.
